(19) United States
(12) Patent Application Publication
(10) Pub. No.: US 2020/0153426 A1
(43) Pub. Date: May 14, 2020

(54) SEMICONDUCTOR INTEGRATED CIRCUIT, DRIVING CIRCUIT FOR HIGH-SIDE TRANSISTOR, AND CONTROLLER FOR DC/DC CONVERTER

(71) Applicant: ROHM CO., LTD., Kyoto (JP)

(72) Inventor: Hiroki NIIKURA, Kyoto (JP)

(21) Appl. No.: 16/681,013

(22) Filed: Nov. 12, 2019

(30) Foreign Application Priority Data
Nov. 14, 2018 (JP) 2018-214145

(51) Int. Cl. H03K 17/567; H03K 17/687; H03K 17/60; H02M 1/08

(52) U.S. Cl. CPC H03K 17/567; H03K 17/6872; H02M 2001/0032; H02M 1/08; H03K 17/602

(57) ABSTRACT

A semiconductor integrated circuit includes a reference circuit including: a first NMOS transistor and a second NMOS transistor having a gate connected in common; and a resistor having one end connected to a source of the first NMOS transistor and the other end connected to a source of the second NMOS transistor, wherein the first NMOS transistor and the second NMOS transistor are formed of floating NMOS transistors

### CROSS-REFERENCE TO RELATED APPLICATION

The present invention claims priority under 35 U.S.C. § 119 to Japanese Patent Application No. 2018-214145, filed on Nov. 14, 2018, the entire contents of which are incorporated herein by reference.

### TECHNICAL FIELD

The present disclosure relates to a semiconductor integrated circuit including a low-voltage malfunction prevention circuit and a reference circuit.

### BACKGROUND

A variety of semiconductor integrated circuits are equipped with a reference circuit (reference voltage source) and an under voltage lock out (UVLO) circuit (low-voltage malfunction prevention circuit). The reference voltage source is a circuit that generates a reference voltage, which does not depend on a power supply voltage or a temperature, and is also referred to as a band gap reference circuit. The UVLO circuit determines whether or not a power supply voltage supplied to a semiconductor integrated circuit exceeds a lower limit voltage (hereinafter referred to as a threshold voltage V_{UVLO}) at which a functional circuit mounted on the semiconductor integrated circuit can operate stably, and stops the operation of the functional circuit when the supplied power supply voltage is lower than the threshold voltage V_{UVLO}. The reference voltage that does not depend on a temperature and a power supply voltage is also used in the UVLO circuit for setting the threshold voltage V_{UVLO}.

FIG. 1 is a circuit diagram of a UVLO circuit 700 reviewed by the present inventor. The UVLO circuit 700 includes NPN type bipolar transistors Q1 and Q2, resistors R1, R2, and Ra to Rc, and transistors M11 to M17.

Assume that currents of the bipolar transistors Q1 and Q2 are I1 and I2, respectively. The current I1 is input to a current mirror circuit CM1 including the transistors M11 and M12. The current I2 is input to a current mirror circuit CM2 including the transistors M13 and M14. The output of the current mirror circuit CM2 is input to a current mirror circuit CM3 including the transistors M15 and M16.

A voltage Vb proportional to an input voltage (power supply voltage) Vcc is generated at a connection node Nb between the resistors Ra and Rb. The voltage Vb is applied to bases of the transistors Q1 and Q2 so as to change a balance between the currents I1 and I2. An impedance balance between the transistors M12 and M16 in an output stage changes depending on a magnitude relationship between the currents I1 and I2, such that a signal UVLO at an output node OUT becomes either high or low. The UVLO circuit 700 basically functions as described above.

A size ratio of the bipolar transistors Q1 and Q2 is 1:N. The base-emitter voltages of the bipolar transistors Q1 and Q2 are assumed to be V_{BE1} and V_{BE2}, respectively. Further, assume that potential of a connection node N1 between the resistors R1 and R2 is Va, a potential of a connection node (base voltages of the bipolar transistor Q1 and Q2) between the resistors Ra and Rb is Vb, and a voltage drop of the resistor R1 is ΔV. Then, the following relational equation, that is, Equation (1) is established.

Vb=Va+V_{BE1}=Va+ΔV+V_{BE2} (1)

Equation (1) can be transformed to obtain below Equation (2).

ΔV=V_{BE1}−V_{BE2} (2)

Further, Equations (3) and (4) below are established for currents flowing into the two bipolar transistors Q1 and Q2.

I1=Is×exp(V_{BE1}/VT) (3)

I2=N×Is×exp(V_{BE2}/V_{T}) (4)

where, V_{T}=k/q×T.

Equations (3) and (4) can be transformed to obtain Equations (5) and (6) below.

V_{BE1}=V_{T}·1n(I1/Is) (5)

V_{BE2}=VT·1n(I2/(N·Is)) (6)

Substituting Equations (5) and (6) into Equation (2) yields Equation (7) below.

ΔV=V_{T}{1n(I1/Is)−1n(I2/(N·Is))}=VT·1n(N×I1/I2) (7)

A state when I1=I2 is used as a boundary between UVLO release and UVLO protection, and Equation (8) is established.

ΔV_{(I1=I2)}=V_{T}×1nN (8)

where ΔAV_{(I1=I2)} is ΔV when I1=I2.

Further, the voltage drop of the resistor R1 is given by Equation (9) below.

I2=ΔV_{(I1=I2)}/R1 (9)

Substituting Equation (8) into Equation (9) yields Equation (10) below.

I2=V_{T}×1nN/R1 (10)

Assume that a threshold value of the UVLO circuit has a hysteresis, an upper threshold value is V_{UVLO+}, and a lower threshold value is V_{UVLO-}. The upper threshold value V_{UVLO+} is first considered. When the output UVLO of the UVLO circuit 700 is high, the transistor M17 is turned on. Therefore, a relationship of Equation (11) is established between a potential Vb_{(I1=I2)} of the node N1 and the input voltage Vcc (that is, V_{UVLO+}).

V_{UVLO+}=Vb_{(I1=I2)}×(Ra/Rb+1) (11)

where Vb_{(I1=I2)} is a potential of the node Nb when I1=I2.

Substituting Equation (1) into Equation (11) yields below Equation (12).

$$\begin{matrix}{V}_{UVLO +} = ( {Va}_{( I 1 + I 2 )} + {V}_{BE 1 ( I 1 + I 2 )} \times ( Ra \text{/} Rb + 1 ) \\ = ( R 2 \times ( I 1 + I 2 ) + {V}_{BE 1 ( I 1 + I 2 )} ) \times ( Ra \text{/} Rb + 1 ) \\ = ( R 2 \times 2 \times I 2 + {V}_{BE 1 ( I 1 + I 2 )} ) \times ( Ra \text{/} Rb + 1 ) \\ = ( R 2 \text{/} R 1 \times 2 \times {V}_{T} \times ln N + {V}_{BE 1 ( I 1 + I 2 )} ) \times ( Ra \text{/} Rb + 1 )\end{matrix} \qquad ( 12 )$$

The lower threshold value V_{UVLO-} is then considered. When the output UVLO of the UVLO circuit 700 is low, the transistor M17 is turned off. Therefore, a relationship of Equation (13) is established between the potential Vb_{(I1=I2)} of the node N1 and the input voltage Vcc (that is, V_{UVLO+}).

V_{UVLO-}=Vb_{(I1=I2)}×(Ra/(Rb+Rc)+1) (13)

Substituting Equation (1) into Equation (13) yields Equation (14) below.

$$\begin{matrix}{V}_{UVLO -} = {Vb}_{( I 1 + I 2 )} \times ( Ra \text{/} ( Rb + Rc ) + 1 ) \\ = ( R 2 \text{/} R 1 \times 2 \times {V}_{T} \times ln N + {V}_{BE 1 ( I 1 + I 2 )} ) \times \\ ( Ra \text{/} ( Rb + Rc ) + 1 )\end{matrix} \qquad ( 14 )$$

In order to cancel the temperature dependency, the partial derivative of Equation (12) with respect to a temperature T should be zero.

$$Δ \text{/} δT \{ ( R 2 \text{/} R 1 \times 2 \times {V}_{T} \times ln N + {V}_{BE 1 ( I 1 + I 2 )} ) \times ( Ra \text{/} Rb + 1 ) \} = R 2 \text{/} R 1 \times 2 \times k \text{/} q \times ln N + α = 0$$

where, α is a temperature coefficient of V_{BE1} and is −1.71 [mV/deg].

Therefore, when Equation (15) is satisfied,

R2=−α×R1/{2×k/q×1n(N)} (15)

V_{T}(=k/q×T) having positive temperature characteristic and V_{BE} having negative temperature characteristic can cancel out with each other, and a temperature-independent threshold value can be set.

As a result of studying the UVLO circuit 700 of FIG. 1, the present inventor has come to recognize the following problems.

In the UVLO circuit 700 of FIG. 1, each of the NPN type bipolar transistors Q1 and Q2 has a PN junction (parasitic diode) between a collector and a substrate (Sub), and has a depletion layer capacitance (parasitic capacitance) C_{SUB} of the PN junction. In a static circuit (circuit that operates with a direct current), an influence of the parasitic capacitance C_{SUB} is not manifested.

However, when the UVLO circuit 700 is integrated on a dynamic semiconductor chip that performs a switching operation, the collector voltages of the bipolar transistors Q1 and Q2 fluctuate due to the influence of the parasitic capacitance C_{SUB}, which causes a malfunction of the UVLO circuit 700.

Although the problems of the UVLO circuit 700 have been described, the same problems occur in a reference voltage source adopting a so-called band gap reference circuit. That is, the band gap reference circuit includes the bipolar transistors Q1 and Q2 and the resistor R1, and like the UVLO circuit 700, has the parasitic capacitance C_{SUB}. Therefore, when the band gap reference circuit is installed in a dynamic circuit that performs a switching operation, the collector voltages fluctuate, which makes it difficult to generate an accurate reference voltage.

### SUMMARY

Some embodiments of the present disclosure provide a semiconductor integrated circuit capable of generating a highly stable reference signal and comparing voltages.

An aspect of the present disclosure provides a semiconductor integrated circuit. The semiconductor integrated circuit includes a reference circuit, which includes a first NMOS transistor and a second NMOS transistor having a gate connected in common, and a resistor having one end connected to a source of the first NMOS transistor and the other end connected to a source of the second NMOS transistor. The first NMOS transistor and the second NMOS transistor are formed of floating NMOS transistors.

Another aspect of the present disclosure provides a semiconductor integrated circuit. The semiconductor integrated circuit includes a power supply line and a low-voltage malfunction prevention circuit configured to receive a voltage of the power supply line. The low-voltage malfunction prevention circuit includes: a first NMOS transistor and a second NMOS transistor having a gate connected in common; a first resistor having a first end connected to a source of the first NMOS transistor and a second end connected to a source of the second NMOS transistor; a second resistor interposed between the second end of the first resistor and a ground line; a voltage division circuit configured to apply a voltage, which is obtained by dividing a voltage of the power supply line, to the gate of the first NMOS transistor and the second NMOS transistor; and an output circuit configured to generate an output signal according to a magnitude relationship between a current flowing through the first NMOS transistor and a current flowing through the second NMOS transistor. The first NMOS transistor and the second NMOS transistor are formed of floating NMOS transistors.

Any combinations of the above-described elements and changes of the elements or representations of the present disclosure among methods, apparatuses, and systems are also effective as aspects of the present disclosure.

### BRIEF DESCRIPTION OF DRAWINGS

FIG. 1 is a circuit diagram of a UVLO circuit studied by the present inventor.

FIG. 2 is a circuit diagram of a semiconductor integrated circuit according to an embodiment.

FIG. 3A and FIG. 3B are a plan view and a cross-sectional view, respectively, showing an element structure of a floating NMOS transistor, respectively.

FIG. 4 is a layout diagram of a first NMOS transistor and a second NMOS transistor.

FIG. 5 is a circuit diagram of a semiconductor integrated circuit according to Example 1.

FIG. 6 is a block diagram of a switching circuit including a UVLO circuit.

FIG. 7 is a circuit diagram of a controller for a DC/DC converter.

FIG. 8 is a circuit diagram of an inverter device.

FIG. 9 is a circuit diagram of a reference voltage source according to Example 2.

FIG. 10 is a circuit diagram of a reference circuit according to Example 3.

### DETAILED DESCRIPTION

Embodiments of the present disclosure will be now described in detail with reference to the drawings. Like or equivalent components, members, and processes illustrated in each drawing are given like reference numerals and a repeated description thereof will be properly omitted. Further, the embodiments are presented by way of example only, and are not intended to limit the present disclosure, and any feature or combination thereof described in the embodiments may not necessarily be essential to the present disclosure.

In the present disclosure, “a state where a member A is connected to a member B” includes a case where the member A and the member B are physically directly connected or even a case where the member A and the member B are indirectly connected through any other member that does not affect an electrical connection state between the members A and B or does not impair functions and effects achieved by combinations of the members A and B.

Similarly, “a state where a member C is installed between a member A and a member B” includes a case where the member A and the member C or the member B and the member C are indirectly connected through any other member that does not affect an electrical connection state between the members A and C or the members B and C or does not impair function and effects achieved by combinations of the members A and C or the members B and C, in addition to a case where the member A and the member C or the member B and the member C are directly connected.

In addition, “a signal A (voltage or current) is according to a signal B (voltage or current)” means that the signal A has a correlation with the signal B. Specifically, it means that (i) the signal A is the signal B, (ii) the signal A is proportional to the signal B, (iii) the signal A is obtained by level-shifting the signal B, (iv) the signal A is obtained by amplifying the signal B, (v) the signal A is obtained by inverting the signal B. or (vi) any combination thereof, and the like. It should be understood by those skilled in the art that a range of “according to” is determined depending on the types and uses of the signals A and B.

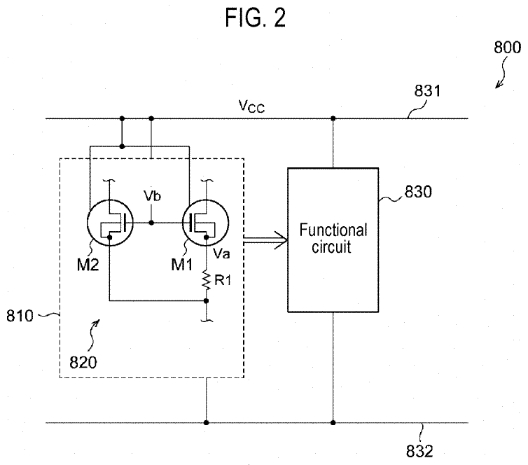

FIG. 2 is a circuit diagram of a semiconductor integrated circuit 800 according to an embodiment. The semiconductor integrated circuit 800 includes a reference circuit 810, a functional circuit 830, a power supply line 831, and a ground line 832. The reference circuit 810 generates a reference signal that does not depend on a power supply voltage Vcc, or provides signal processing using the reference signal. The reference signal may be a reference voltage, a reference current, or a threshold voltage. It is to be understood by those skilled in the art that the type of the reference signal is determined by a configuration of a peripheral circuit of the reference circuit 810. A potential of the ground line 832 is not necessarily fixed, but it may be switched, as will be described later. An output of the reference circuit 810 is supplied to the functional circuit 830.

The reference circuit 810 includes a basic circuit element 820. The basic circuit element 820 includes a first NMOS transistor M1, a second NMOS transistor M2, and a resistor R1. Gates of the first NMOS transistor M1 and the second NMOS transistor M2 are connected in common. One end of the resistor R1 is connected to a source of the first NMOS transistor M1, and the other end of the resistor R1 is connected to a source of the second NMOS transistor M2.

The first NMOS transistor M1 and the second NMOS transistor M2 are formed of floating NMOS transistors. A size ratio (W1/L1:W2/L2) of the first NMOS transistor M1 and the second NMOS transistor M2 is 1:K. Here, W denotes a gate width and L denotes a gate length.

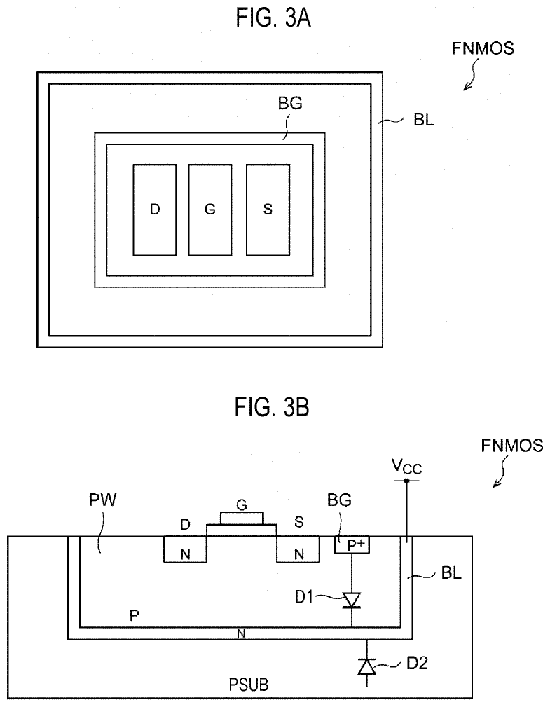

FIG. 3A and FIG. 3B are a plan view and a cross-sectional view, respectively, showing an element structure of a floating NMOS (FNMOS) transistor. A structure of a transistor formed on a P-type silicon substrate PSUB will be described with reference to FIG. 3A and FIG. 3B. A periphery and lower side of the floating NMOS transistor are surrounded by an isolation layer BL (a so-called buried layer) in which N-type impurities are diffused.

An N-type drain region D and an N-type source region S are formed in a P-type well PW surrounded by the isolation layer BL, and a gate insulating film and a gate electrode are formed in a gate region G between the drain region D and the source region S. A P-type back gate region BG is formed inside the P-type well so as to surround the drain region D, the gate region G, and the source region S. A first PN junction (diode) D1 is formed between the back gate BG and the isolation layer BL, and a second PN junction D2 is formed between the P-type substrate PSUB and the isolation layer BL. Cathodes of the PN junctions D1 and D2 face each other so as to form a PNP type parasitic bipolar transistor. The isolation layer BL (that is, a base of the parasitic bipolar transistor) is connected to a power supply line, thus preventing an influence of the parasitic bipolar transistor from conducting unintentionally.

In the structure of the FNMOS transistor, the gate G, the source S, the drain D, and the back gate BG may be isolated from the substrate PSUB, but the structure of the FNMOS transistor structure is not limited to that shown in FIG. 3.

Returning to FIG. 2, it is assumed that a current flowing through the first NMOS transistor M1 and a current flowing through the second NMOS transistor M2 are I1 and I2, respectively. Element sizes (W/L) and bias states of the first NMOS transistor M1 and the second NMOS transistor M2 are determined so as to have a sub-threshold region when I1=I2.

A configuration of the semiconductor integrated circuit 800 is as described above. Next, an operation of the semiconductor integrated circuit 800 will be described. The reference circuit 810 is used (as a reference voltage source or as a reference current source) by being biased to establish a state where I1=I2, or is used (as a UVLO circuit) with the state where I1=I2 as a boundary (threshold value). Therefore, the state where I1=I2 will be considered.

Since the first NMOS transistor M1 and the second NMOS transistor M2 operate in the sub-threshold region, their drain currents are given by Equation (16) below.

$${I}_{D} = μ {C}_{d} \frac{W}{L} {V}_{T}^{2} ( exp ( \frac{{V}_{GS} - {V}_{TH}}{ζ {V}_{T}} ) ) ( 1 - exp ( \frac{- {V}_{DS}}{{V}_{T}} ) ) \\ {V}_{T} = \frac{k T}{q} , ζ = 1 + \frac{{C}_{d}}{{C}_{ox}} \\ S = 2.3 {V}_{T} ( 1 + \frac{{C}_{d}}{{C}_{ox}} ) = 2.3 \frac{k T}{q} ζ \qquad ( 16 )$$

A voltage drop ΔV of the resistor R1 is given by Equation (17) below.

ΔV=V_{GS1}−V_{GS2} (17)

The gate-source voltage in the sub-threshold region is expressed by Equation (18) below.

V_{GS}=V_{TH}+S×1n(Id/(W/L)×I₀) (18)

When I1=I2, Equation (17) is transformed to obtain Equation (19) below.

$$Δ V = {V}_{GS 1} - {V}_{GS 2} = ξ \times k \text{/} q \times T \times ln ( {I}_{D 1} \text{/} {I}_{D 2} ) = ξ \times k \text{/} q \times T \times ln ( ( W 2 \text{/} L 2 ) \text{/} ( W 1 \text{/} L 1 ) ) = ξ \times k \text{/} q \times T \times ln ( K ) \qquad ( 19 )$$

Since ΔV=I2×R1, the current I1 of the second NMOS transistor M2 (and the current I2 of the first NMOS transistor M1) in the balanced state (I1=I2) is expressed by Equation (20) below.

$$I 2 = I 1 = Δ V \text{/} R 1 = ξ \times k \text{/} q \times T \times ln ( K ) \text{/} R 1 \qquad ( 20 )$$

The current expressed by Equation (20) is a constant current that does not depend on the power supply voltage Vcc. Focusing on this characteristic, it can be understood that the basic circuit element 820 can be used to form a reference current source.

As is clear from Equation (17), it can be seen that ΔV has a positive temperature characteristic when I1=I2, as in the bipolar transistor. As will be described later, by using the basic circuit element 820, a reference signal having no temperature dependency can be generated, or a UVLO circuit having a flat temperature characteristic can be provided.

The configuration of the semiconductor integrated circuit 800 is as described above. According to the semiconductor integrated circuit 800, since the back gate BG, the source S, the gate G, and the drain D of each of the first NMOS transistor M1 and the second NMOS transistor M2 are isolated from the substrate PSUB, an influence of fluctuation of a potential of the substrate PSUB can be reduced.

Instead of using the floating NMOS transistor, an approach of using a silicon on insulator (SOI) substrate, in which single crystalline silicon is formed on an insulating film, as a substrate is also conceivable. However, since the SOI substrate is more expensive than a normal silicon substrate, the semiconductor integrated circuit 800 according to the embodiment is advantageous from the viewpoint of cost over this approach.

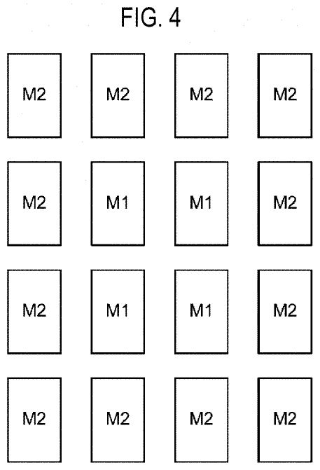

FIG. 4 is a layout diagram of the first NMOS transistor M1 and the second NMOS transistor M2. Considering a case of K=3, the first NMOS transistor M1 and the second NMOS transistor M2 include sixteen transistor units (cells) arranged in a 4×4 matrix. Four central cells may be assigned for the first NMOS transistor M1, and twelve cells surrounding the central cells may be assigned for the second NMOS transistor M2. According to this layout, the pair property of the first NMOS transistor M1 and the second NMOS transistor M2 can be improved.

The present disclosure may be understood by the block diagram or circuit diagram of FIG. 2, and covers various devices and circuits derived from the above description. However, the present disclosure is not limited to specific configurations. Hereinafter, more specific examples and modifications will be described in order to aid understanding of the nature and circuit operation of the present disclosure and clarify them, rather than to narrow the scope of the present disclosure.

### Example 1

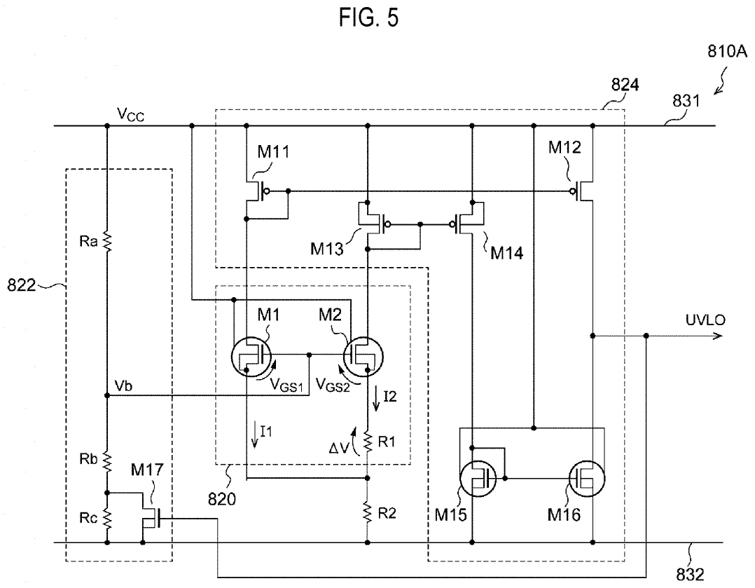

FIG. 5 is a circuit diagram of a semiconductor integrated circuit according to Example 1. The semiconductor integrated circuit includes a UVLO circuit 810A. The UVLO circuit 810A includes a resistor R2, a voltage division circuit 822, and an output circuit 824 in addition to the basic circuit element 820 of FIG. 2.

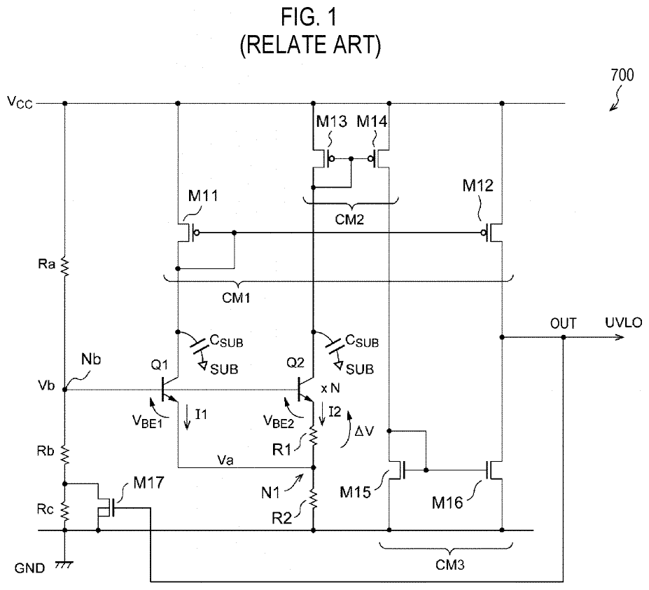

The voltage division circuit 822 divides the voltage Vcc of the power supply line 831 and supplies a voltage Vb, which is obtained from the division of the voltage Vcc, to the gates of the first NMOS transistor M1 and the second NMOS transistor M2. A voltage division ratio of the voltage division circuit 822 switches between two values according to an output (high/low) of the UVLO circuit 810A. The configuration of the voltage division circuit 822 is the same as that in FIG. 1.

The output circuit 824 is a comparison circuit that compares the current I1 flowing through the first NMOS transistor M1 with the current I2 flowing through the second NMOS transistor M2, and generates an output UVLO indicating a magnitude relationship between the two currents I1 and I2. The output circuit 824 includes transistors M11 to M16. The transistors M11 and M12 form a first current mirror circuit which replicates the current I1 of the first NMOS transistor M1. The transistors M13 and M14 form a second current mirror circuit which replicates the current I2 of the second NMOS transistor M2. The transistors M15 and M16 form a third current mirror circuit which replicates the current of the transistor M14. Depending on the magnitude relationship between the currents I1 and I2, the impedance balance of the transistors M12 and M16 in the output stage changes, and the voltage level of the output node is set to be either high or low.

Similar to the first NMOS transistor M1 and the second NMOS transistor M2, the transistors M15 and M16 are formed of floating NMOS transistors, and isolation layers BL of the transistors M15 and M16 are connected to the power supply line 831.

The configuration of the UVLO circuit 810A is as described above. The operation of the UVLO circuit 810A is the same as that of the UVLO circuit 700 of FIG. 1. The temperature dependency of the UVLO circuit 810A will be described below.

The upper threshold value V_{UVLO+} of UVLO can be obtained by replacing the term V_{T}×1nN+V_{BE1(I1=I2)} in Equation (12) with ζ×k/q×T×1n(K)+V_{GS1}, and is expressed by Equation (21) below.

V_{UVLO+}=(R2/R1×2×ζ×k/q×T×1n(K)+V_{GS1})×(Ra/Rb+1) (21)

Similarly, the lower threshold value V_{UVLO-} of UVLO can be obtained by replacing the term V_{T}×1nN+V_{BE1(I1+I2)} in Equation (13) with ζ×k/q×T×1n(K)+V_{GS1}, and is expressed by Equation (22) below.

V_{UVLO-}=(R2/R1×2×ζ×k/q×T×1n(K)+V_{GS1})×(Ra/(Rb+Rc)+1) (22)

A condition that the temperature dependency of the threshold value V_{UVLO+} becomes zero is that the partial derivative of Equation (21) with respect to the temperature is zero.

(R2/R1×2×ζ×k/q×1n(K)+β)=0

where β is a differential of V_{GS} and is −2.60 [mV/deg].

Therefore, by determining the resistors R1 and R2 so as to satisfy below Equation (23), the threshold values V_{UVLO+} and V_{UVLO-} that do not depend on temperature can be obtained.

R2/R1=−β/{2×ζ×k/q×1n(K)} (23)

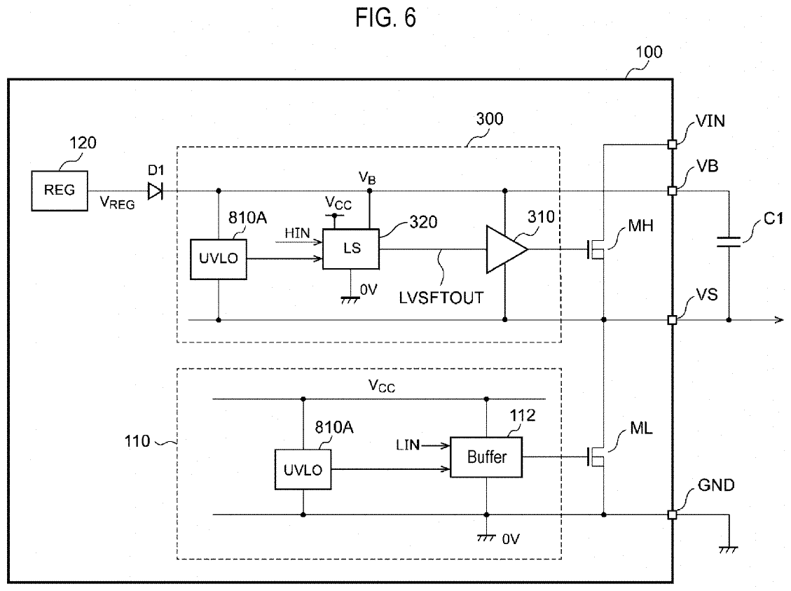

Next, the usage of the UVLO circuit 810A will be described. FIG. 6 is a block diagram of a switching circuit 100 including the UVLO circuit 810A.

The switching circuit 100 includes an input (VIN) pin, a bootstrap (VB) pin, a switching (VS) pin, and a ground (GND) pin. In the following description, the pins are also referred to as terminals or lines.

The switching circuit 100 is an integrated circuit (IC) in which a high-side transistor MH, a low-side transistor ML, a high-side driving circuit 300, and a low-side driving circuit 110 are integrated in a semiconductor chip.

The high-side transistor MH is of an N-channel or an NPN type, and is interposed between the VIN pin and the VS pin. The low-side transistor ML is of the same type as the high-side transistor MH, and is interposed between the VS pin and the GND pin. The switching circuit 100 generates a power supply voltage V_{B}, which is higher than an input voltage V_{IN} on the VB line, by a so-called bootstrap circuit. A regulator 120 generates a stabilized internal voltage V_{REG} and charges a bootstrap capacitor C1 through a diode D1. When a DC voltage stabilized at a suitable voltage level is supplied from an external power supply to the switching circuit 100, the regulator 120 may be omitted.

The low-side driving circuit 110 drives the low-side transistor ML based on a control signal LIN.

The high-side driving circuit 300 drives the high-side transistor MH based on a control signal HIN. The high-side driving circuit (hereinafter also simply referred to as a driving circuit) 300 includes a buffer (driver) 310, a level shift circuit 320, and the UVLO circuit 810A.

The level shift circuit 320 converts the input signal HIN, which has a logical level for setting the GND pin voltage to a low level and a power supply voltage V_{CC} to a high level, into an intermediate signal LVSFTOUT for setting the voltage V_{B} of the bootstrap line VB to a high level and a voltage Vs of the switching line VS to a low level. The buffer 310 drives the high-side transistor MH in response to the signal LVSFTOUT output from the level shift circuit 320.

The driving circuit 300 operates using the VB line as an upper power supply line (power supply plane) and using the VS line as a lower power supply line (ground plane). When the voltage V_{S} of the VS line switches between the input voltage V_{IN} and the ground voltage 0 V, the voltage V_{B} of the VB line also switches while maintaining a certain potential difference from the voltage V_{S}. This potential difference corresponds to a power supply voltage of a high-side circuit block.

The UVLO circuit 810A compares the potential difference between the VB line and the VS line with the predetermined threshold values V_{UVLO+} and V_{UVLO-}. The power supply line 831 and the ground line 832 in FIG. 5 correspond to the VB line and the VS line in FIG. 6, respectively.

In a circuit block where the ground line (ground plane) as shown in FIG. 6 is switched, when the UVLO circuit of FIG. 1 is adopted, potentials of collectors of bipolar transistors are affected by the switching, which makes it impossible to make a correct UVLO determination. On the other hand, when the UVLO circuit 810A of FIG. 5 is adopted, the influence of the switching can be eliminated, which makes it possible to make an accurate UVLO determination.

In addition, as shown in FIG. 6, the UVLO circuit 810A can be used for the low-side driving circuit 110 as well. Since the low-side ground plane is grounded and ideally is not affected by switching, the UVLO circuit 700 of FIG. 1 can be used. However, in reality, since there is a non-negligible impedance component between the GND line and the external ground, the potential of the GND line is affected by switching. Therefore, by also adopting the UVLO circuit 810A on the low side, it is possible to make an accurate UVLO determination.

### (Applications)

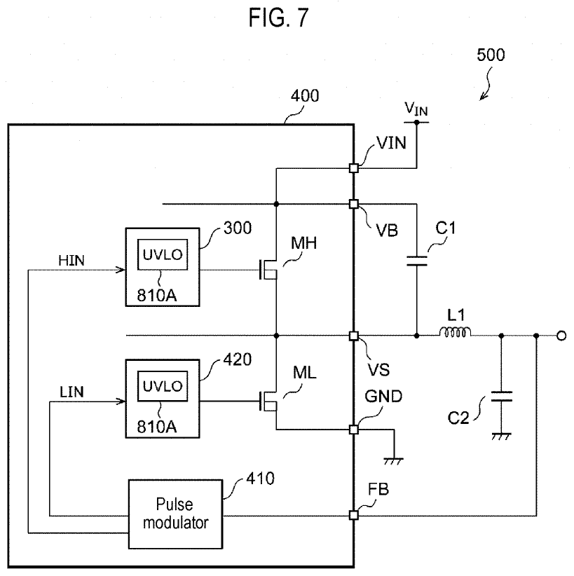

Next, applications of the driving circuit 300 will be described. The driving circuit 300 can be used for a DC/DC converter. FIG. 7 is a circuit diagram of a controller 400 for a DC/DC converter 500. The DC/DC converter 500 is a synchronous rectification buck converter and includes capacitors C1 and C2 and an inductor L1 in addition to the controller 400.

The controller 400 includes a high-side transistor MH, a low-side transistor ML, a pulse modulator 410, a low-side driving circuit 420, and a driving circuit (high-side driving circuit) 300. The pulse modulator 410 generates pulse signals HIN and LIN such that an output (output voltage, output current, or load state) of the DC/DC converter 500 approaches a target value. For example, the pulse modulator 410 may bring an output voltage V_{OUT} close to a target voltage V_{REF} (constant voltage control), or may bring an output current I_{OUT} close to a target current I_{REF} (constant current control).

The high-side driving circuit 300 drives the high-side transistor MH of an N-channel or NPN type based on the pulse signal HIN. The low-side driving circuit 420 drives the low-side transistor ML based on the pulse signal LIN.

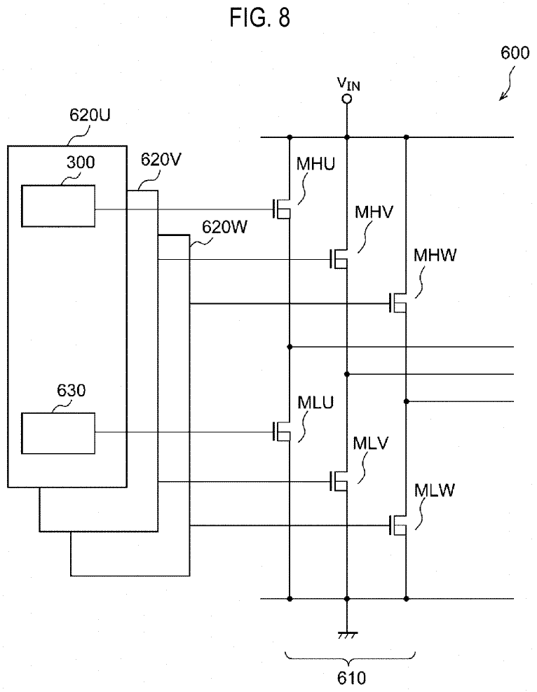

The driving circuit 300 may also be used for an inverter device. FIG. 8 is a circuit diagram of an inverter device 600. The inverter device 600 includes a three-phase inverter 610 and U-phase, V-phase, and W-phase driving circuits 620U, 620V, and 620W, respectively. The three-phase inverter 610 includes high-side transistors MHU, MHV, and MHW and low-side transistors MLU, MLV, and MLW. The driving circuit 620# (#=U, V, W) includes a high-side driving circuit 300 and a low side-driving circuit 630.

### Example 2

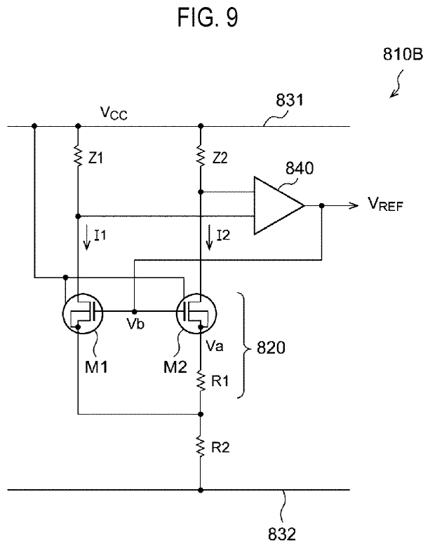

FIG. 9 is a circuit diagram of a reference voltage source 810B according to Example 2. The reference voltage source 810B includes a resistor R2, impedance elements Z1 and Z2, and a feedback circuit (amplifier) 840, in addition to the basic circuit element 820. The impedance elements Z1 and Z2 are connected to the drains of the transistors M1 and M2, respectively. The feedback circuit 840 adjusts the gate voltages Vb of the transistors M1 and M2 so that voltage drops of the impedance elements Z1 and Z2 are equal to each other, that is, I1=I2. The impedance elements may be a resistor or a transistor.

### Example 3

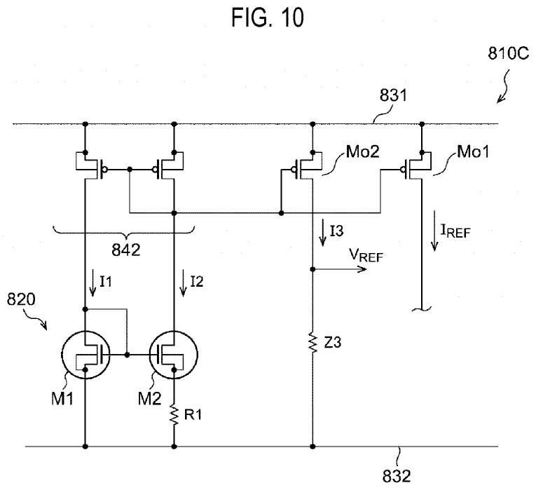

FIG. 10 is a circuit diagram of a reference circuit 810C according to Example 3. The reference circuit 810C includes a current mirror circuit 842 in addition to the basic circuit element 820. An input of the current mirror circuit 842 is connected to the second NMOS transistor M2, and an output of the current mirror circuit 842 is connected to the first NMOS transistor M1. A feedback is applied to make I1=I2 by the current mirror circuit 842.

The reference circuit 810C may further include an output transistor Mo1. The output transistor Mo1 copies the current I2 and outputs it as a reference current I_{REF} that does not depend on the power supply voltage Vcc.

The reference circuit 810C may further include an output transistor Mo2 and an impedance element Z3. The output transistor Mo2 may copy the current I2 and supply a current I3 to the impedance element Z3 to generate a reference voltage V_{REF}.

The present disclosure has been described above by way of embodiments. The disclosed embodiments are illustrative only. It should be understood by those skilled in the art that various modifications to combinations of elements or processes may be made and such modifications fall within the scope of the present disclosure. Such modifications will be described below.

### Modification 1

Although FIG. 3 illustrates a case where a P-type semiconductor substrate is used, an N-type semiconductor substrate may be used. In this case, the P type and the N type may be read interchangeably.

### Modification 2

In the embodiment, the high-side transistor MH has been described as an N-channel MOSFET, but the high-side transistor MH may be an NPN type bipolar transistor or an IGBT. In such a case, the gate, source, and drain may be read as a base, emitter, and collector, respectively.

### Modification 3

In the embodiment, a case where the high-side transistor MH is integrated in the same IC as that of the driving circuit 300 has been described. However, the present disclosure is not limited thereto. For example, the high-side transistor MH may be a discrete component.

### Modification 4

In the DC/DC converter 500 of FIG. 7, the low-side transistor ML may be replaced with a diode. Further, the topology of the DC/DC converter 500 is not limited to a buck type, and may be configured with other types that include a high-side transistor.

### Modification 5

The application of the switching circuit 100 is not limited to a DC/DC converter and an inverter device. For example, the switching circuit 100 may be applied to a bidirectional converter, a battery charging circuit, a class D amplifier for audio, and so on.

According to the present disclosure in some embodiments, it is possible to provide a semiconductor integrated circuit capable of generating a highly stable reference signal or comparing voltages.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit comprising:
a reference circuit including:
a first NMOS transistor and a second NMOS transistor having a gate connected in common; and
a resistor having one end connected to a source of the first NMOS transistor and the other end connected to a source of the second NMOS transistor,
wherein the first NMOS transistor and the second NMOS transistor are formed of floating NMOS transistors.

2. The semiconductor integrated circuit of claim 1, wherein an isolation layer surrounding each of the first NMOS transistor and the second NMOS transistor is connected to a power supply line.

3. The semiconductor integrated circuit of claim 1, wherein each of the first NMOS transistor and the second NMOS transistor includes a plurality of transistor cells of the same size, and wherein the plurality of transistor cells forming the second NMOS transistor surround the plurality of transistor cells forming the first NMOS transistor.

4. The semiconductor integrated circuit of claim 1, wherein a potential of a ground line is switched, and a semiconductor substrate is grounded.

5. The semiconductor integrated circuit of claim 1, wherein the reference circuit further includes a current mirror circuit that copies a current of the first NMOS transistor and supplies the copied current to the first NMOS transistor.

6. A semiconductor integrated circuit comprising:
a power supply line; and
a low-voltage malfunction prevention circuit configured to receive a voltage of the power supply line,
wherein the low-voltage malfunction prevention circuit includes:
a first NMOS transistor and a second NMOS transistor having a gate connected in common;
a first resistor having a first end connected to a source of the first NMOS transistor and a second end connected to a source of the second NMOS transistor;
a second resistor interposed between the second end of the first resistor and a ground line;
a voltage division circuit configured to apply a voltage, which is obtained by dividing a voltage of the power supply line, to the gate of the first NMOS transistor and the second NMOS transistor; and
an output circuit configured to generate an output signal according to a magnitude relationship between a current flowing through the first NMOS transistor and a current flowing through the second NMOS transistor, and
wherein the first NMOS transistor and the second NMOS transistor are formed of floating NMOS transistors.

7. The semiconductor integrated circuit of claim 6, wherein an isolation layer surrounding each of the first NMOS transistor and the second NMOS transistor is connected to the power supply line.

8. The semiconductor integrated circuit of claim 6, wherein a potential of the ground line is switched, and a semiconductor substrate is grounded.

9. A driving circuit for a high-side transistor of an N-channel or an NPN type, the driving circuit comprising;
a level shift circuit configured to shift a level of an input signal;
a driver configured to drive the high-side transistor in response to an output of the level shift circuit;
a switching line connected to a source of the high-side transistor;
a high-side power supply line; and
a low-voltage malfunction prevention circuit configured to ground the switching line and monitor a voltage of the high-side power supply line,
wherein the low-voltage malfunction prevention circuit includes:
a first NMOS transistor and a second NMOS transistor having a gate connected in common;
a first resistor having a first end connected to a source of the first NMOS transistor and a second end connected to a source of the second NMOS transistor;
a second resistor interposed between the second end of the first resistor and a ground line;
a voltage division circuit configured to apply a voltage, which is obtained by dividing the voltage of the high-side power supply line, to the gate of the first NMOS transistor and the second NMOS transistor; and
an output circuit configured to generate an output signal according to a magnitude relationship between a current flowing through the first NMOS transistor and a current flowing through the second NMOS transistor, and
wherein the first NMOS transistor and the second NMOS transistor are formed of floating NMOS transistors.

10. The driving circuit of claim 9, wherein an isolation layer surrounding each of the first NMOS transistor and the second NMOS transistor is connected to the high-side power supply line.

11. The driving circuit of claim 9, wherein each of the first NMOS transistor and the second NMOS transistor includes a plurality of transistor cells of the same size, and
wherein the plurality of transistor cells forming the second NMOS transistor surround the plurality of transistor cells forming the first NMOS transistor.

12. The driving circuit of claim 9, wherein the voltage of the high-side power supply line is generated by a bootstrap circuit.

13. A controller for a DC/DC converter controller, the controller comprising:
a pulse modulator configured to generate a pulse signal so that an output of the DC/DC converter approaches a target value; and
a high-side driving circuit configured to drive an N-channel or NPN type high-side transistor based on the pulse signal,
wherein the high-side driving circuit includes the driving circuit of claim 9.

14. The controller of claim 13, further comprising a low-side driving circuit configured to drive an N-channel or NPN type low-side transistor based on the pulse signal,
wherein the low-side driving circuit includes a low-voltage malfunction prevention circuit having the same structure as the low-voltage malfunction prevention circuit of the high-side driving circuit.
